(19) United States
(12) Patent Application Publication
(10) Pub. No.: US 2026/0143705 A1
(43) Pub. Date: May 21, 2026

(54) VERTICAL PLANAR CELLS WITH IN-PILLAR CHANNEL STRUCTURES

(71) Applicant: Micron Technology, Inc., Boise, ID (US)

(72) Inventors: Jun Fujiki, Boise, ID (US); Matthew J. King, Boise, ID (US); Yoshiaki Fukuzumi, Yokohama (JP)

(21) Appl. No.: 19/377,972

(22) Filed: Nov. 3, 2025

Related U.S. Application Data
(60) Provisional application No. 63/723,499, filed on Nov. 21, 2024.

(51) Int. Cl. H10B 43/27; H10B 43/10; H10B 43/35

(52) U.S. Cl. CPC H10B 43/27; H10B 43/10; H10B 43/35

(57) ABSTRACT

Methods, systems, apparatuses, and devices for vertical planar cells with in-pillar channel structures are described. The described techniques provide for memory cell channels to be formed relatively close to other memory cell channels within a portion of a stack of materials. For example, the described techniques support forming recesses within a pillar or slot and forming memory cell channels within respective recesses, such that a separation material prevents or mitigates interference from a memory cell channel in an adjacent recess. In some examples, a cavity may grant access to an adjacent slot or pillar such that notches of separation material may be formed to separate memory cell channels within the slot or pillar.

### CROSS REFERENCE

The present Application for Patent claims priority to U.S. patent application Ser. No. 63/723,499 by Fujiki et al., entitled “VERTICAL PLANAR CELLS WITH IN-PILLAR CHANNEL STRUCTURES,” filed Nov. 21, 2024, which is assigned to the assignee hereof, and which is expressly incorporated by reference in its entirety herein.

### TECHNICAL FIELD

The following relates to one or more systems and apparatuses for memory, including an apparatus including vertical planar cells with in-pillar channel structures.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of an apparatus that supports vertical planar cells with in-pillar channel structures in accordance with examples as disclosed herein.

FIGS. 2A through 2E show examples of a memory architecture that supports vertical planar cells with in-pillar channel structures in accordance with examples as disclosed herein.

FIGS. 3A through 3G show examples of a memory architecture that supports vertical planar cells with in-pillar channel structures in accordance with examples as disclosed herein.

FIG. 4 shows an example of a memory architecture that supports vertical planar cells with in-pillar channel structures in accordance with examples as disclosed herein.

### DETAILED DESCRIPTION

Some memory systems (e.g., apparatuses) include vertical planar memory cells or in-pillar memory cells, where the memory cell transistors may be connected within a stack of materials formed on a substrate (e.g., a 3D not-and (NAND) memory configuration). In some examples, such memory cell configurations may increase a density of memory cells deposited within the stack of materials, where memory cells may be accessed via one or more memory cell channels extending through the stack. The memory cell channels may be formed relatively close to one another (e.g., within a pillar or slot formed in the stack), thereby further increasing memory cell density and improving capabilities of a memory system including the stack of materials. However, memory cell channels being in close proximity to one another may increase a likelihood of interference or shorting between memory cell channels, and some memory system configurations may be unable to support such memory cell channel structures.

Techniques, systems, apparatuses, and devices described herein provide for memory cell channels to be formed relatively close to other memory cell channels within a portion of a stack of materials (e.g., a group of memory cell channels formed within a pillar or a slot of the stack of materials). For example, the described techniques may support forming recesses within a pillar or slot and forming memory cell channels within respective recesses, such that a separation material prevents or mitigates interference from a memory cell channel in an adjacent recess. In one example, a central pillar (e.g., a dummy pillar) may enable access to surrounding pillars (e.g., memory cell channel pillars), where material can be selectively oxidized within the surrounding pillars to form the recesses for memory cell channels. In another example, a sacrificial material (e.g., a polymer material, a nitride material) may form boundaries across pillars in the stack of materials. For example, pillar cavities may enable access to sidewall regions between adjacent pillars, where the sacrificial material may be inserted. The sacrificial material may extend into the pillars and may ultimately be replaced with a metal material (e.g., during a metallization process) associated with one or more access lines for accessing memory cells. The metal material may form one or more notches in the pillar. For example, the metal material may protrude, or otherwise extend some distance within the pillar. Each notch of metal material may be relatively thin and spaced apart from other notches of the metal material, such that recesses are formed between notches of the metal material. Similar techniques may be applied to a slot of memory cell channels, where recesses are formed on respective sidewalls of the slot. Such techniques may enable increase memory cell channel density, which may improve overall performance of the memory system.

In addition to applicability in memory systems as described herein, techniques for vertical planar cells with in-pillar channel structures may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by increasing memory cell density, which may improve overall performance and capabilities of the electronic devices, thereby improving user experience, among other benefits.

Features of the disclosure are illustrated and described in the context of systems, devices, and circuits. Features of the disclosure are further illustrated and described in the context of memory architectures.

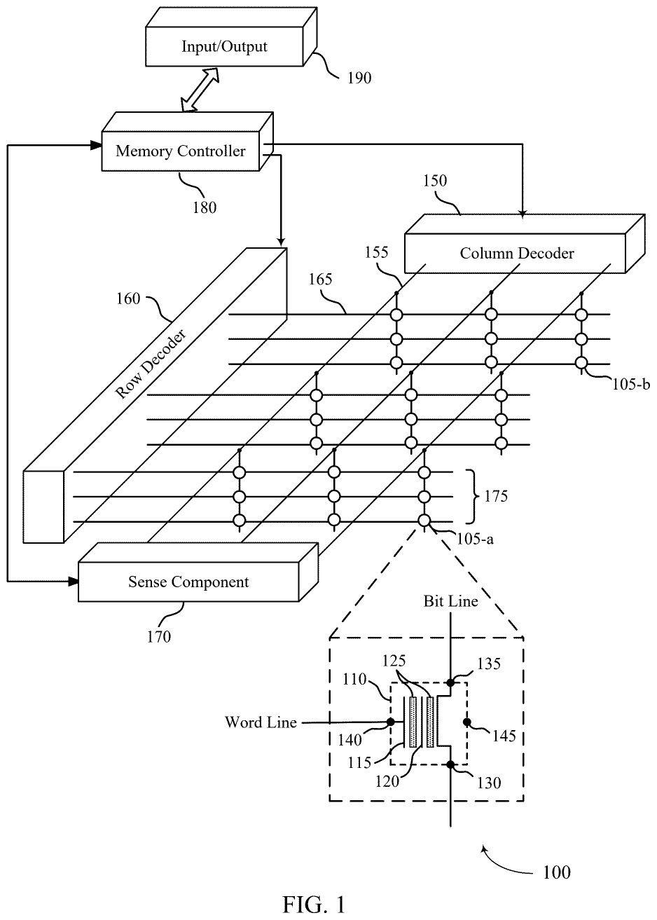

FIG. 1 shows an example of an apparatus 100 that supports vertical planar cells with in-pillar channel structures in accordance with examples as disclosed herein. FIG. 1 is an illustrative representation of various components and features of the apparatus 100. As such, the components and features of the apparatus 100 are shown to illustrate functional interrelationships, and not necessarily physical positions within the apparatus 100. Further, although some elements included in FIG. 1 are labeled with a numeric indicator, some other corresponding elements are not labeled, even though they are the same or would be understood to be similar, in an effort to increase visibility and clarity of the depicted features.

The apparatus 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

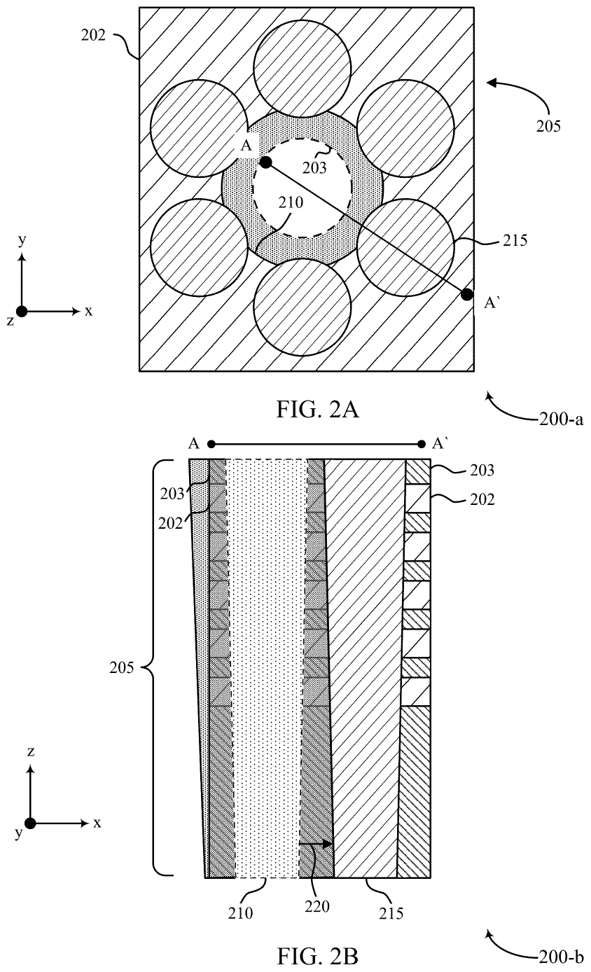

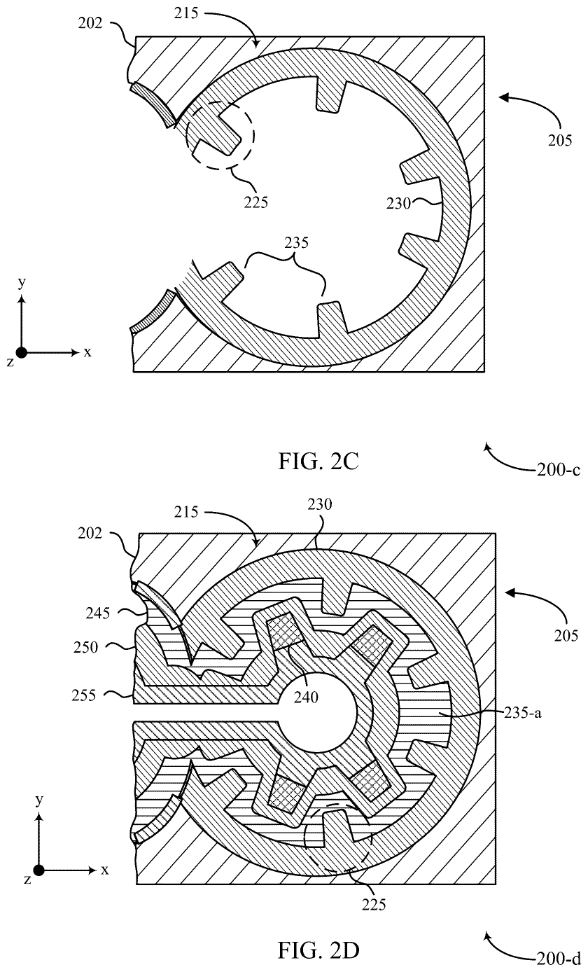

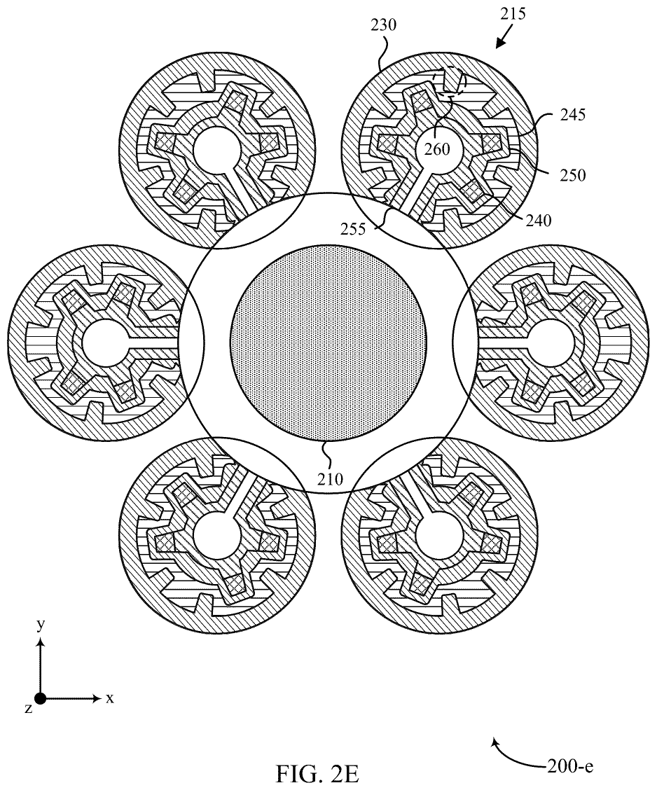

In some cases, an apparatus 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, apparatus 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of apparatus 100.

Some apparatuses 100 (e.g., memory systems) include vertical planar memory cells or in-pillar memory cells 105, where the memory cell transistors may be connected within a stack of materials formed on a substrate (e.g., a 3D NAND memory configuration). In some examples, such memory cell 105 configurations may increase a density of memory cells 105 deposited within the stack of materials, where memory cells 105 may be accessed via one or more memory cell channels extending through the stack. The memory cell channels may be formed relatively close to one another (e.g., within a pillar or slot formed in the stack), thereby further increasing memory cell 105 density and improving capabilities of a memory system including the stack of materials. However, memory cell channels being in close proximity to one another may increase a likelihood of interference or shorting between memory cell channels, and some memory system configurations may be unable to support such memory cell channel structures.

Techniques, systems, and devices described herein provide for memory cell channels to be formed relatively close to other memory cell channels within a portion of a stack of materials (e.g., a group of memory cell channels formed within a pillar or a slot of the stack of materials). For example, the described techniques may support forming recesses within a pillar or slot and forming memory cell channels within respective recesses, such that a separation material prevents or mitigates interference from a memory cell channel in an adjacent recess. In one example, a central pillar (e.g., a dummy pillar) may enable access to surrounding pillars (e.g., memory cell channel pillars), where material can be selectively oxidized within the surrounding pillars to form the recesses for memory cell channels. In another example, a sacrificial material (e.g., a polymer material, a nitride material) may form boundaries across pillars in the stack of materials. For example, pillar cavities may enable access to sidewall regions between adjacent pillars, where the sacrificial material may be inserted. The sacrificial material may extend into the pillars and be replaced with a metal material, such that recesses are formed between notches of the metal material. Similar techniques may be applied to a slot of memory cell channels, where recesses are formed on respective sidewalls of the slot. Such techniques may enable increase memory cell channel density, which may improve overall performance of the apparatus 100.

FIGS. 2A through 2E show examples of memory architectures 200 after various processing steps that support formation of an apparatus including vertical planar cells with in-pillar channel structures as described herein. The memory architectures 200 may be an example of a portion of an apparatus, such as an apparatus 100 described with reference to FIG. 1. FIGS. 2A through 2E show various views and steps of forming a memory architecture 200. For example, the memory architectures 200 may illustrate operations associated with forming an apparatus including memory cell channels extending into a stack of materials. In some cases, the memory architectures 200 may support memory cell channels being separated, within a memory pillar, by a separation material, which may improve memory cell density while mitigating interference between memory cell channels.

For illustrative purposes, aspects of the memory architecture may be described with reference to an x-direction, a y-direction, and a z-direction of the illustrated coordinate systems. For example, memory architectures 200-a, 200-b, 200-c, 200-d, and 200-e illustrate the memory architecture from cross-sectional and/or planar views, to illustrate a cross-section of the memory architecture in the xz-plane, the xy-plane, or both. Although the memory architectures 200 illustrate examples of relative dimensions and quantities of various features, aspects of the memory architectures 200 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIGS. 2A through 2E may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 2A illustrates an example of a memory architecture 200-a after one or more first processing steps associated with forming memory cell channels within pillars formed in a stack of materials 205. The stack of materials 205 may be formed above a substrate and may include layers of one or more materials. For example, the memory architecture 200-a shows a top layer of the stack of materials 205, which may be made of or otherwise include a sacrificial material 202. The stack of materials 205 may include one or more additional layers of the sacrificial material 202 and one or more layers of an oxide material 203, as described in greater detail with reference to FIG. 2B. In some cases, one or more pillars may be formed in the stack of materials 205 (e.g., the pillars may extend from the top layer of the stack of materials 205 towards the substrate in the z direction). For example, a central pillar 210 may be formed from a first hole in the stack of materials 205, and may be associated with accessing one or more surrounding memory pillars 215 (e.g., memory cell channel pillars) formed from one or more second holes in the stack of materials 205.

It is to be understood that the stack of materials 205 may include additional pillars not shown by the memory architectures 200. The pillars may be formed from an array of holes patterning a surface of the stack of materials 205, where multiple groups of pillars, including a central pillar 210 and surrounding memory pillars 215, may be included in the stack of materials 205. Additionally, or alternatively, the central pillar 210 may be associated with any quantity of surrounding pillars 215 (e.g., according to the pattern and quantity of holes formed in the stack of materials 205), and is not limited to the examples illustrated by the memory architectures 200. For example, the memory pillars 215 may include six pillars positioned in a hexagonal shape around the central pillar 210 (e.g., as illustrated by FIG. 2A), or may include four pillars positioned in a square shape around the central pillar 210, among other examples.

The one or more first processing steps may include forming the stack of materials 205 including alternating layers of the oxide material 203 and the sacrificial material 202. After the stack is formed, one or more holes may be formed via one or more etch or exhume processes. For example, multiple holes may be formed by removing materials from the stack of materials 205 in accordance with some hole formation pattern (e.g., using masks, for example), such that multiple holes extend from a top surface of the stack of materials 205 to the substrate in the z-direction. The memory pillars 215 may be formed from these holes (e.g., cavities where the layers of the stack of materials 205 have been removed) in the stack of materials 205. For example, the one or more processing steps may include filling the holes with one or more materials. Each memory pillar 215 may include a sidewall of an oxide material (e.g., a blocking oxide), a first trim material lining the sidewall of the oxide material (e.g., a polysilicon sacrificial material), a second trim material lining the first trim material (e.g., a nitride sacrificial material), and a core fill material (e.g., carbon nitride) within the remaining space of the pillar 215. The central pillar 210 may additionally include these materials, and the materials may be exhumed or otherwise removed from the central pillar 210 to support accessing the memory pillars 215. Although referred to as a central pillar 210, it is to be understood that the central pillar 210 may represent an example of a hole or cavity or some other cylindrically-shaped absence of material through the stack of materials 205.

In some examples, a portion of the sacrificial material 202 in each layer of the sacrificial material 202 may be removed to form one or more recesses around the central pillar 210. As such, a portion of the oxide material 203 may remain, such that a cavity in each layer of the sacrificial material 202 may be larger than (e.g., associated with a greater diameter than) a cavity in each layer of the oxide material 203. Such recessing is described in further detail with reference to FIG. 2B.

FIG. 2B illustrates an example of a memory architecture 200-b after one or more second processing steps associated with accessing the memory pillars 215 via the central pillar 210. The memory architecture 200-b illustrates a cross-sectional view along the A-A′ line shown in FIG. 2A. The memory architecture 200-b shows an example of the layers of the stack of materials 205, which include one or more layers of the sacrificial material 202 and one or more layers of the oxide material 203. In some examples, the one or more layers of the sacrificial material 202 may alternate with the one or more layers of the oxide material 203, and the alternating layers may extend to the bottom of the stack of materials 205.

The memory architecture 200-b shows the central pillar 210 and a memory pillar 215. In the example illustrated by the memory architecture 200-b, the central pillar 210 may be exhumed (e.g., a cavity) and the memory pillar 215 may include an oxide material, a first trim material, a second trim material, and a core fill material described with reference to FIG. 2A. To support accessing the memory pillar 215 via the central pillar 210, an operation 220 may be performed to remove the layers of the stack of materials 205 between the central pillar 210 and the memory pillar 215. For example, the operation 220 may be an example of an etch that removes a portion of each of the one or more layers of the sacrificial material 202 and a portion of each the one or more layers of the oxide material 203 such that the memory pillar 215 is exposed via the central pillar 210. In some cases, material between the central pillar 210 and the memory pillar 215 may be removed until reaching the first trim material in the memory pillar 215 (e.g., the operation 220 may remove a portion of the sidewall of oxide material within the memory pillar 215). The operation 220 may be similarly performed between the central pillar 210 and one or more other memory pillars 215 surrounding the central pillar 210 (e.g., one central pillar 210 may provide access to multiple memory pillars 215).

FIG. 2C illustrates an example of a memory architecture 200-c after one or more third processing steps associated with forming recesses for memory cell channels within a memory pillar 215. For example, the memory architecture 200-c illustrates an example of a memory pillar 215 including one or more segments 225 of a separation material 230. In some cases, the separation material 230 may be the oxide lines extending along at least a portion of the sidewall of the memory pillar 215 as described with reference to FIG. 2A. The one or more segments 225 (e.g., notches, extrusions of the separation material 230) may form recesses 235 for memory cell channels, which may separate the memory cell channels to prevent interference. For example, each segment 225 of the one or more segments 225 may extend through the stack in the vertical direction (e.g., the z direction) and may be separated from each other segment 225 to form the recesses 235.

In some cases, the segments 225 may be formed by selectively oxidizing portions of the first trim material that lines the sidewall of the separation material 230 of the memory pillar 215. For example, the first trim material may be etched until reaching a location of a segment 225. The first trim material may be oxidized (e.g., a portion of the first trim material becomes an oxide material) to form a segment 225 of the separation material 230, and the second trim material may be etched to the location of the segment 225. The first trim material may iteratively be etched and selectively oxidized to form each segment 225 of the separation material 230, and the second trim material may be etched such that no trim material remains after forming the segments 225 (e.g., all trim material is etched away or oxidized to form segments 225). Additionally, the core fill material may be removed after forming the segments 225, which may result in the apparatus illustrated by FIG. 2C. Similar operations may be performed for each memory pillar 215 accessed by a central pillar 210 to form segments 225 and recesses 235 that support forming memory cell channels in each respective memory pillar 215.

In some cases, the memory architecture 200-c may include six segments 225, as illustrated by FIG. 2C. When the memory architecture 200-c includes six segments 225, the recesses 235 may support forming four memory cell channels or five memory cell channels. Alternatively, the memory architecture 200-c may include four segments 225. When the memory architecture 200-c includes four segments 225, the recesses 235 may support forming two memory cell channels or three memory cell channels.

FIG. 2D illustrates an example of a memory architecture 200-d after one or more fourth processing steps associated with forming memory cell channels 240 in a memory pillar 215. In some cases, the one or more fourth processing steps may include depositing one or more materials into the memory pillar 215 of the memory architecture 200-c to support forming a memory cell channel 240 within one or more recesses 235 of the memory pillar 215.

In some cases, a storage material 245 may be deposited into the memory pillar 215. For example, the storage material 245 (e.g., a storage nitride) may extend along the separation material 230 at the sidewall of the memory pillar 215, such that the storage material 245 lines each segment 225 and each recess 235. Additionally, a second separation material 250 (e.g., a tunnel oxide) may be deposited such that the second separation material 250 lines the storage material 245 in the memory pillar 215. In some cases, the storage material 245 and the second separation material 250 may be deposited into the central pillar 210 in addition to or as part of depositing the storage material 245 and the second separation material 250 into the memory pillar 215. In some examples, the materials may be deposited through the central pillar 210 into each pillar 215 that is in the same group as the central pillar 210 (e.g., the pillars 215 illustrated in FIG. 2A).

After depositing the storage material 245 and the second separation material 250 into the memory pillar 215, the memory cell channels 240 may be deposited. For example, a metal material may be deposited to extend along the second separation material 250 to form a memory cell channel 240 in the remaining space of each recess 235. The metal material may be etched to separate the memory cell channels 240 and an oxide terminate 255 may be deposited to isolate each memory cell channel 240 (e.g., each memory cell channel 240 may be at least partially surrounded by oxide material, as second separation material). In some cases, the second separation material 250 may be positioned between each memory cell channel 240 such that each memory cell channel 240 is separate within the memory pillar 215.

In some examples, the memory architecture 200-d may support a fifth memory cell channel 240 (e.g., in addition to the four memory cell channels 240 illustrated by FIG. 2D). For example, the fifth memory cell channel 240 may be formed in the recess 235-a, which may be positioned on the end (e.g., in the x-direction) of the pillar 215 in FIG. 2D (e.g., illustrated as a vacant recess in FIG. 2D). Additionally, or alternatively, the recess 235-d may not include a memory cell channel, as illustrated in FIG. 2D. For example, the recess 235-d may be slightly smaller than the other recesses 235, in some examples.

FIG. 2E illustrates an example of a memory architecture 200-e after one or more fifth processing steps associated with forming memory cell channels 240 within memory pillars 215. The memory architecture 200-e shows an example of a group of memory pillars 215 (which may be referred to as second pillars) accessed via the central pillar 210 (which may be referred to as a first pillar) and each including a respective set of memory cell channels 240. In some cases, the memory architecture 200-e may be formed within the stack of materials 205 illustrated in FIGS. 2A through 2D. The memory architecture 200-e may illustrate a zoomed out version of the memory architecture 200-d after the one or more fifth processing steps, in some examples. For example, the memory architecture 200-e may include the pillar 215 illustrated in FIG. 2D, as well as five other pillars 215 that at least partially surround (e.g., are positioned around) a central pillar 210, which may be filled with a placeholder material, in some examples. In the example illustrated by the memory architecture 200-e, each memory pillar 215 may include the separation material 230, the storage material 245, the second separation material 250, and the oxide terminate 255, as described herein. In some examples, the notches of the separation material 230 illustrated in FIG. 2D may be exhumed or otherwise replaced with the second separation material 250, as illustrated in FIG. 2E. In some examples, the notches may be relatively more triangular after the replacement with the second separation material 250.

The one or more fifth processing steps may include removing (e.g., etching, exhuming) one or more materials from the central pillar 210 and a central region of each of the pillars 215. For example, a portion of each of the second separation material 250, the separation material 230, the storage material 245, and the oxide terminate 255 may be removed from the central pillar 210, a region between the central pillar 210 and each of the pillars 215, and from a portion of each of the pillars 215. Such removal may form one or more recesses (e.g., two recesses in each pillar 215 in the example of FIG. 2E) within each pillar 215. The one or more fifth processing steps may further include oxidizing, after removing the materials, an exposed portion of the oxide terminate 255 to form portions 260 of the oxide terminate that extend into each memory cell channel 240. The portions 260 may be in the shape of a triangle, or some other shape. The one or more fifth processing steps may further include The one or more fifth processing steps may further include a metallization operation. For example, one or more layers of the sacrificial material 202 in the stack of materials illustrated in FIG. 2D may be replaced by one or more layers of a metal material (e.g., to form word lines) during a metallization and replacement gate operation, such that the stack of materials includes alternating layers of the metal material and the oxide material. In some cases, each memory cell channel 240 of each memory pillar 215 may be coupled with multiple memory cells within the stack of materials 205 (e.g., a vertical NAND string). For example, a memory cell channel 240 may couple with a memory cell including the storage material 245 within each layer of the metal material within the stack of materials 205 (e.g., at each crosspoint between the metal material and the memory channel 240). A bit line contact (not pictured) may couple with each memory channel 240 in each respective memory pillar 215 to connect each memory pillar 215 to a respective bit line (e.g., to enable selection of a certain memory pillar 215). A given memory cell may be activated via activation of an associated word line and bit line. The memory architecture 200-e supports increased memory cell density while preventing interference between memory cell channels 240 by separating memory cell channels 240 with a separation material within a memory pillar 215.

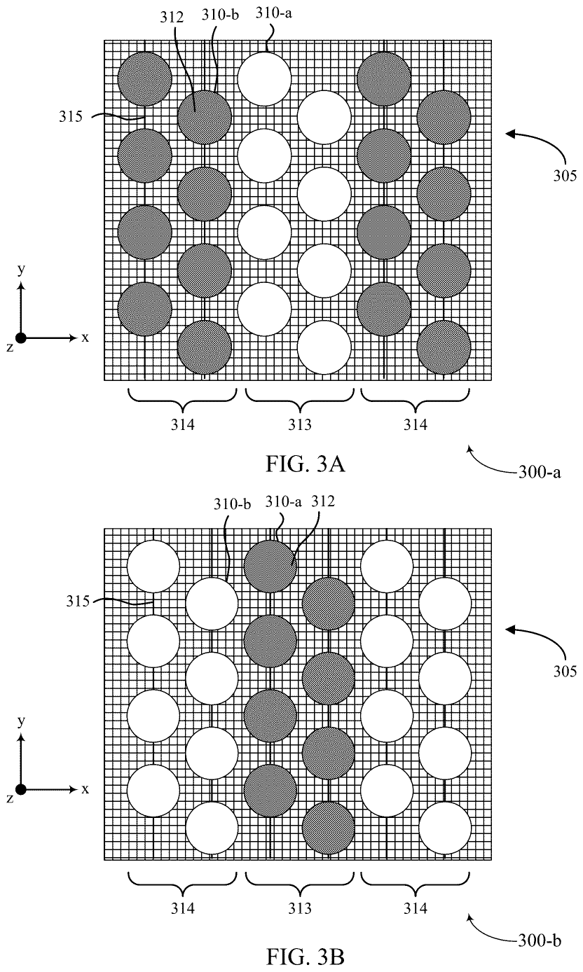

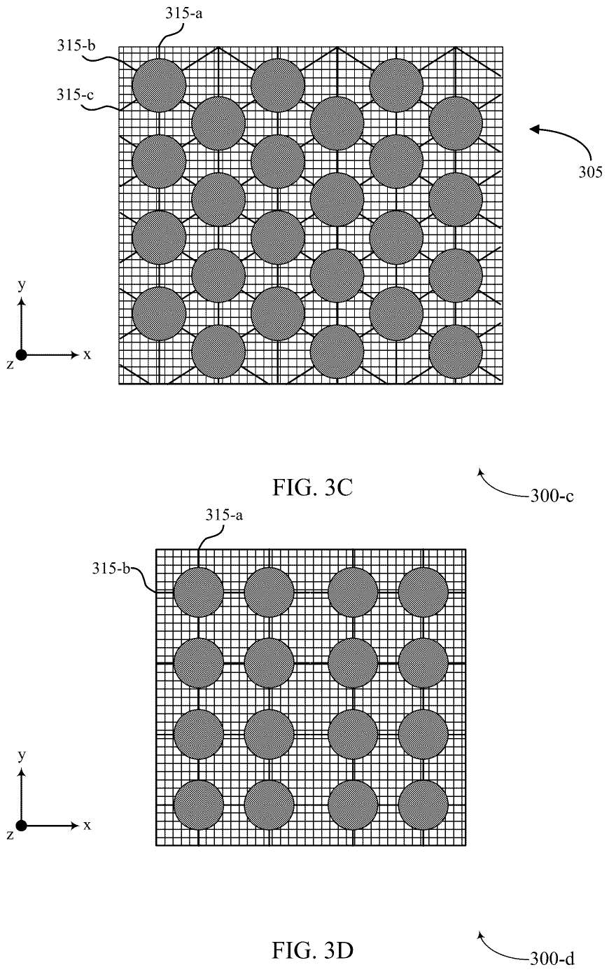

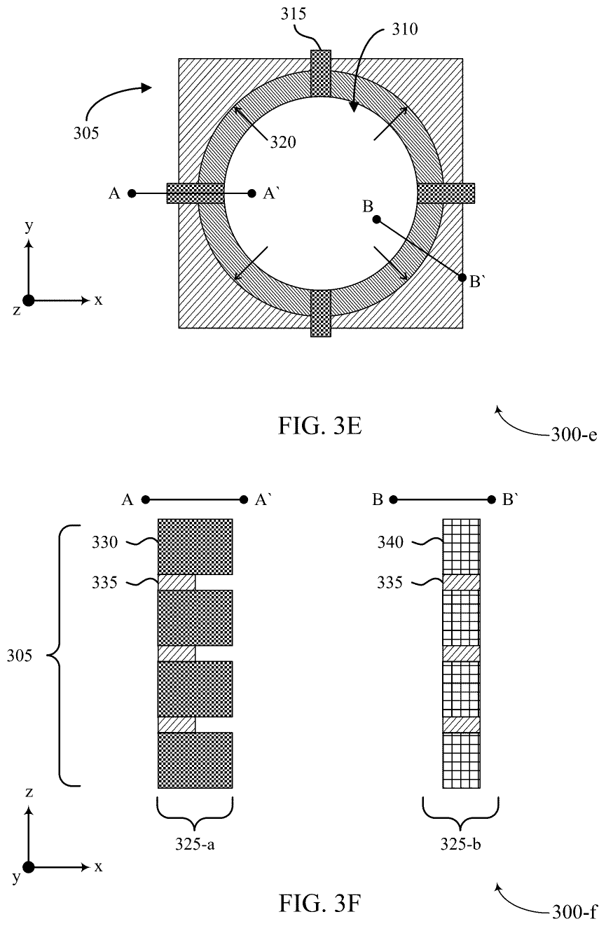

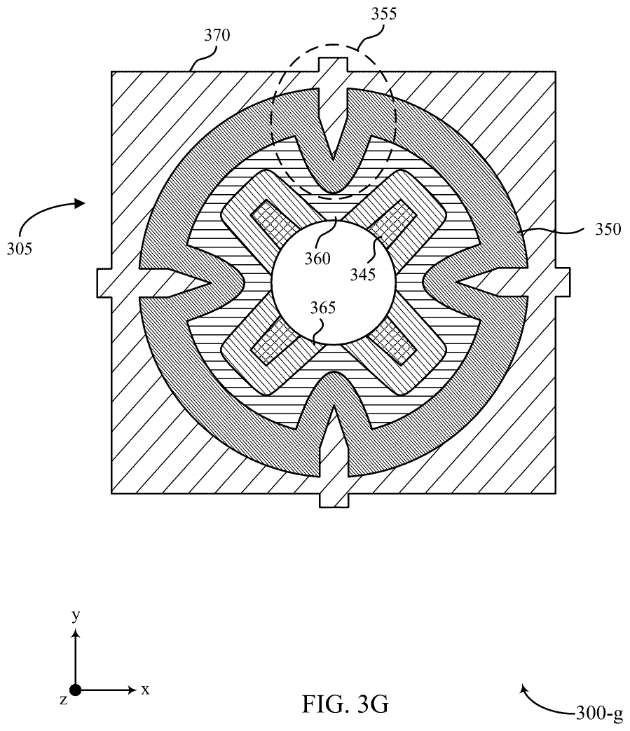

FIGS. 3A through 3G show examples of memory architectures 300 after various processing steps that support vertical planar cells with in-pillar channel structures as described herein. The memory architectures 300 may be an example of a portion of an apparatus, such as an apparatus 100 described with reference to FIG. 1. FIGS. 3A through 3G show various views and steps of forming a memory architecture 300. For example, the memory architectures 300 may illustrate operations associated with forming an apparatus including memory cell channels extending into a stack of materials. In some cases, the memory architectures 300 may support memory cell channels being separated, within a memory pillar, which may improve memory cell density while mitigating interference between memory cell channels.

For illustrative purposes, aspects of the memory architecture 300 may be described with reference to an x-direction, a y-direction, and a z-direction of the illustrated coordinate systems. For example, memory architectures 300-a, 300-b, 300-c, 300-d, 300-e, 300-f, and 300-g illustrate the memory architecture from cross-sectional and/or planar views, to illustrate a cross-section of the memory architecture in the xz-plane, the xy-plane, or both. Although the memory architectures 300 illustrate examples of relative dimensions and quantities of various features, aspects of the memory architectures 300 may be implemented with other relative dimensions or quantities of such features in accordance with examples as disclosed herein. In the following description of the processing steps, some methods, techniques, processes, and operations may be performed in different orders or at different times. Further, some operations may be left out of the processing steps, or other operations may be added to the processing steps. Although described as singular processing steps, it is to be understood that each processing step may include one or more multiple processing operations, including, but not limited to, formations, depositions, etches, removals, exhumes, other processing steps, or the like.

Processing steps illustrated in and described with reference to FIGS. 3A through 3G may be performed by a manufacturing system, such as a semiconductor fabrication system configured to perform additive operations such as deposition, formation, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 3A illustrates an example of a memory architecture 300-a after one or more first processing steps associated with forming memory cell channels within pillars 310 formed in a stack of materials 305. The stack of materials 305 may be formed above a substrate and may include layers of one or more materials. For example, the stack of materials 305 may include one or more layers of a sacrificial material and one or more layers of an oxide material. In some cases, one or more pillars 310 may be formed in the stack of materials 305 (e.g., the pillars may extend from the top layer of the stack of materials 205 towards the substrate in the z direction). For example, in the xy-plane, one or more columns of pillars 310 may be formed in the stack of materials 305, where the columns may be formed at staggered heights in the y-direction, as illustrated by FIG. 3A. Each pillar 310 may be a hole or cavity that extends from a top surface of the stack of materials 305 through to a substrate below the stack of materials 305 or at least partway through the stack of materials 305. After the holes are formed, some or all of the pillars 310 may be filled with a placeholder material 312.

The one or more first processing steps may include forming the stack of materials 305 and the holes through the stack of materials. Additionally, the placeholder material may be formed in the holes. The placeholder material 312 may be removed (e.g., etched, exhumed) from a first set of pillars 313, which may include two columns of pillars, in some examples. In some cases, the memory architecture 300-a may support forming sacrificial material (e.g., a polymer material) boundaries 315 at sidewalls between memory pillars 310. The staggered columns of pillars 310 may allow for sidewall regions to be accessed between pillars 310, such that by exhuming the first set of pillars 313 (e.g., material may be removed to form a hole or cavity), the first set of pillars 313 may be used to support forming a sacrificial material boundary 315 at respective sidewall regions of adjacent second sets of pillars 314. For example, a pillar 310-a may be exhumed and used to form the sacrificial material boundary 315 at a sidewall of a pillar 310-b. In some cases, forming the sacrificial material boundary 315 may include recessing layers of sacrificial material in the stack of materials 305 (e.g., recessing nitride tiers) from the pillar 310-a to a central axis of the pillar 310-b and depositing the sacrificial material to form the boundary 315. In such examples, layers of the oxide material in the stack of materials 305 may not be recessed, such that the sacrificial material boundary 315 is formed within layers of sacrificial material, and the oxide material remains between each layer. In some cases, one exhumed pillar 310 may support forming sacrificial material boundaries 315 for two adjacent columns, as illustrated by FIG. 3A. Each pillar 310 of a column of exhumed pillars 310 may be used to form the sacrificial material boundaries 315 at adjacent pillars 310 (e.g., the sacrificial material boundaries 315 extend along a length of the stack of materials 305, broken by pillars 310).

FIG. 3B illustrates an example of a memory architecture 300-b after one or more second processing steps associated with forming memory cell channels within pillars 310 formed in the stack of materials 305. The memory architecture 300-b shows an example of the one or more second processing steps applied to the memory architecture 300-a. For example, the one or more second processing steps may include depositing the placeholder material 312 in the first set of pillars 313, which were previously-exhumed pillars 310 (e.g., the pillar 310-a) and exhuming the placeholder material 312 from the previously filled pillars 310 in the second sets of pillars 314 after the sacrificial material boundary 315 is formed. The second sets of pillars 314, once exhumed, may grant access to the previously-exhumed pillars 310 of the first set of pillars 313 so the sacrificial material boundaries 315 may be formed for each column of pillars 310 in the first set of pillars 313.

FIG. 3C illustrates an example of a memory architecture 300-c after one or more third processing steps associated with forming memory cell channels within pillars 310 formed in the stack of materials 305. The memory architecture 300-c shows an example of additional sacrificial material boundaries 315 being formed in the memory architecture 300-b. For example, the processing steps of FIG. 3B may result in forming a sacrificial material boundary 315-a that extends along the surface of the stack of materials 305 in the y direction at each column of pillars 310. Similar processing steps may be applied to form sacrificial material boundaries 315-b and 315-c that extend diagonally (e.g., extending with portions of each of the x direction and the y direction) across the surface of the stack of materials 305. For example, sets of pillars 310 (e.g., columns of pillars 310, rows of pillars 310, or some other arrangement of pillars 310) may be exhumed to provide access to sidewall of adjacent pillars 310 for forming the sacrificial material boundaries 315-b and 315-c. In the example illustrated by the memory architecture 300-c, each pillar 310 may include six points of contact with the sacrificial material boundary (e.g., two points of contact per sacrificial material boundary 315).

FIG. 3D illustrates an example of a memory architecture 300-d after one or more third processing steps associated with forming memory cell channels within pillars 310 formed in the stack of materials 305. The memory architecture 300-d shows an example of additional sacrificial material boundaries 315 being formed in the memory architecture 300-b. For example, the processing steps of FIG. 3B may result in forming a sacrificial material boundary 315-a that extends along the surface of the stack of materials 305 in the y direction at each column of pillars 310. Similar processing steps may be applied to form a sacrificial material boundary 315-b that extends horizontally along the surface of the stack of materials 305 in the x direction at each row of pillars 310. For example, rows of pillars 310 may be exhumed to provide access to sidewall of adjacent rows of pillars 310 for forming the sacrificial material boundary 315-b at each pillar 310. In the example illustrated by the memory architecture 300-c, each pillar 310 may include four points of contact with the sacrificial material boundary (e.g., two points of contact per sacrificial material boundary 315).

FIG. 3E illustrates an example of a memory architecture 300-e after one or more fourth processing steps associated with forming memory cell channels within pillars 310 of the stack of materials 305. The memory architecture 300-e shows a zoomed in view of a pillar 310 (e.g., a memory pillar within the stack of materials 305) that contacts one or more sacrificial material boundaries 315. In the example illustrated by the memory architecture 300-e, the pillar 310 contacts a sacrificial material boundary 315 at four points: at a sidewall of the pillar 310 directly above, below, to the left, and to the right of the center of the pillar 310 when viewing the pillar 310 from a top-down view in the xy-plane (e.g., the configuration illustrated by the memory architecture 300-d). It should be noted that the pillar 310 may support any configuration of sacrificial material boundaries 315, such as the configuration illustrated by the memory architecture 300-c having six points of contact with a sacrificial material boundary 315, or any other suitable configuration. In some cases, an operation 320 may be performed to recess a portion of the sidewall of the pillar 310. The operation 320 may include etching the layers of the stack of materials 305 while not etching the sacrificial material of the sacrificial material boundaries 315.

FIG. 3F illustrates an example of a memory architecture 300-f after the one or more fourth processing steps associated with forming memory cell channels within pillars 310 of the stack of materials 305. The memory architecture 300-f shows a sidewall portion 325-a and a sidewall portion 325-b, which may be portions of a sidewall of the pillar 310 described with reference to FIG. 3E. For example, the sidewall portion 325-a illustrates a cross-sectional view along the A-A′ line shown in FIG. 3E and the sidewall portion 325-b illustrates a cross-sectional view along the B-B′ line shown in FIG. 3E.

The sidewall portion 325-a may be an example of a portion of the sidewall of the pillar 310 that contacts a sacrificial material boundary 315. For example, the sidewall portion 325-a may include one or more layers of a sacrificial material 330 (e.g., a polymer material) corresponding to the sacrificial material boundary 315. The sidewall portion 325-a may include one or more layers of an oxide material 335, which may be oxide layers deposited when forming the stack of materials 305. In some cases, the operation 320 may result in the one or more layers of the oxide material 335 being recessed a first length without recessing the one or more layers of the sacrificial material 330, such that the one or more layers of the sacrificial material 330 (e.g., the sacrificial material boundary 315) extend further into the pillar 310 than the one or more layers of the oxide material 335. Similar techniques may occur at each sacrificial material boundary 315 that contacts the pillar 310, such that the sacrificial material 330 extends further into the pillar 310 than the oxide material 335 at each sacrificial material boundary 315.

The sidewall portion 325-b may be an example of a portion of the sidewall of the pillar 310 that does not contact a sacrificial material boundary 315 (e.g., a portion where the sacrificial material 330 was not deposited to form a sacrificial material boundary 315). For example, the sidewall portion 325-b may include one or more layers of a sacrificial material 340 (e.g., a nitride material) and one or more layers of the oxide material 335. In some cases, the operation 320 may result in the one or more layers of the sacrificial material 340 and the one or more layers of the oxide material being recessed the first length.

FIG. 3G illustrates an example of a memory architecture 300-g after one or more fifth processing steps associated with forming memory cell channels within pillars 310 of the stack of materials 305. The memory architecture 300-g illustrates a pillar 310 after forming one or more memory cell channels 345 in the pillar 310.

The one or more fifth processing steps may include depositing a separation material 350 to extend along the sidewall of the pillar 310. For example, the separation material 350 (e.g., a blocking oxide material) may be deposited after performing the operation 320 to recess the sidewall of the pillar 310 and expose the sacrificial material boundaries 315. Depositing the separation material 350 may result in the separation material lining the sidewall of the pillar 310 and forming one or more notches 355. The notches 355 may be formed based on the separation material 350 lining the exposed portions of the sacrificial material 330 (e.g., corresponding to sacrificial material boundaries 315) that extend into the pillar 310. In some examples, the formation of the separation material 350 may alter a shape of the sacrificial material boundaries 315 illustrated in FIG. 3E. For example, the separation material 350 may form around the sacrificial material boundaries 315 and may recess or otherwise etch a portion of the sacrificial material boundaries to form a pointed shape that tapers into the pillar 310 (e.g., a V-shape or other tapered shape). In some cases, a storage material 360 (e.g., a storage nitride) may be deposited after depositing the separation material 350. For example, the storage material 360 may line the sidewall of the pillar 310 and may extend along the separation material 350.

In some cases, a second separation material 365 (e.g., a tunnel oxide) may be deposited after depositing the storage material 360 and may line the sidewall of the pillar 310. After depositing the second separation material 365, a metal material for the memory cell channels 345 may be deposited in a recess formed by depositing the other materials. For example, each memory cell channel 345 may be deposited in a recess originating from a space between each notch 355, and may be separated from other memory cell channels 345 based on extending between at least two notches 355. It should be noted that while the memory architecture 300-g illustrates a pillar 310 that includes four memory cell channels (e.g., due to four points of contact with a sacrificial material boundary as shown in the memory architecture 300-d), the pillar 310 may support any quantity of memory cell channels 345, such as six memory cell channels 345 in accordance with the configuration shown by the memory architecture 300-e.

In some examples, a replacement gate procedure may be performed on the apparatus before or after forming the one or more additional materials. For example, the layers of sacrificial material 340 that form the sacrificial material boundaries 315 and the layers of sacrificial material 330 within the stack of materials 305 may be removed via a sacrificial material exhume operation, and a metal material 370 may be inserted in the cavities formed after removing the sacrificial material 340 and the sacrificial material 330. The metal material 370 may form multiple word lines at each layer of the metal material 370, where each word line may at least partially surround the pillar 310 and may include a portion of the metal material 370 within each notch 355. That is, the sacrificial material 340, when removed, may form tapered cavities that extend into the separation material 350 in the pillar 310. When the metal material 370 is formed, the metal material 370 may fill the tapered cavities to form the notches 355, which may be tapered notches in the pillar 310 corresponding to protrusions of the metal material. Sidewalls of the pillar 310 may be defined by the separation material 350, in some examples, such that the notches 355 of the metal material 370 may protrude into the pillar 310.

In some cases, each memory cell channel 345 may be coupled with multiple memory cells that include the storage material 360 within the layers of the metal material 370. For example, there may be a memory cell at each intersection point between a memory cell channel 345 and the metal material 370, which may be referred to as a memory cell pillar, in some examples (e.g., a stack of memory cells in the z-direction). By forming the notches 355, the memory cells in each memory cell channel 345 may be independently selectable from memory cells in other memory cell channels 345, and there may not be interference between two or more adjacent memory cell channels 345.

The memory architecture 300-g thereby supports increased memory cell density while preventing interference between memory cell channels 345 by separating memory cell channels 345 with a separation material within a pillar 310. The memory cells may be accessed via activation of one or more respective word lines (e.g., layers of the metal material 370) and a bit line (not pictured), which may be coupled with the memory cell channels 345 via a bit line contact on top of the pillar 310 in the z-direction.

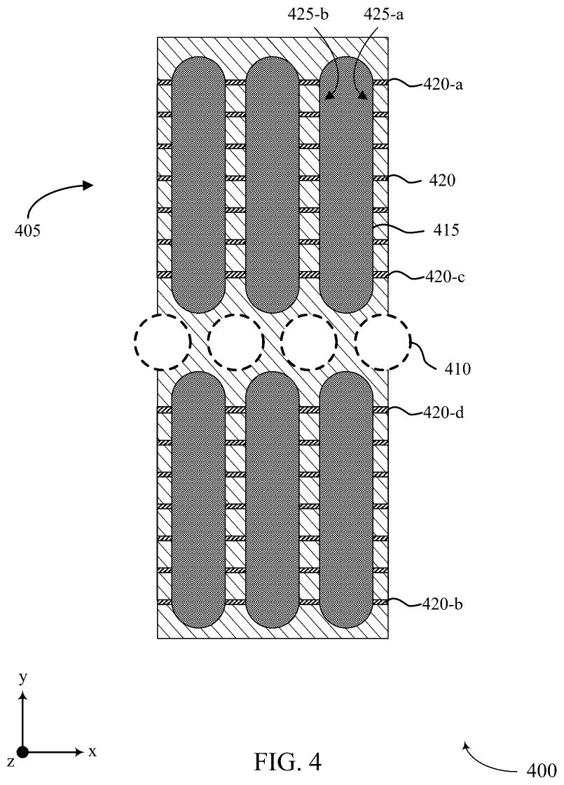

FIG. 4 illustrates an example of a memory architecture 400 that supports vertical planar cells with in-pillar channel structures as described herein. The memory architecture 400 may be an example of a portion of an apparatus, such as an apparatus 100 described with reference to FIG. 1. The memory architecture 400 may be an example of a stack of materials 405 formed above a substrate, which may be examples of corresponding aspects described herein. For example, the stack of materials 405 may be formed from one or more layers of an oxide material and one or more layers of a sacrificial material, which may be formed in an alternating pattern.

In some cases, the memory architecture 400 may support forming memory cell channels within one or more memory slots 415. The memory slots 415 may extend through the stack of materials 405 in a vertical direction (e.g., towards the substrate) and may extend along the stack of materials 405 (e.g., relative to a surface of the stack of materials 405) such that each memory slot 415 includes a first sidewall 425-a and a second sidewall 425-b. In some cases, one or more holes 410 may provide access to sidewall regions between memory slots 415. For example, each hole 410 may be formed by exhuming material from the stack of materials 405. Each hole 410 (e.g., cavity, recess) may include an absence of material in a cylindrical or other shape that extends through at least a portion of the stack of materials 405 and may be used to etch material from sidewall regions between memory slots 415.

The holes 410 may be used to form sacrificial material boundaries 420 at the sidewalls 425 of each memory slot 415. The sacrificial material boundaries 420 may be formed using techniques similar to those described with reference to FIGS. 3A through 3G. For example, the one or more layers of sacrificial material (e.g., the nitride material) of the stack of materials 405 may be removed and selectively replaced with a second sacrificial material (e.g., a polymer material) to form the sacrificial material boundaries 420. The sacrificial material boundaries 420 may be formed in multiple phases. For example, all or most of the sacrificial material may be removed from the stack of materials 405, and a first sacrificial material boundary 420-a and a second sacrificial material boundary 420-b may be formed by replacing a surface of the remaining sacrificial material with a second sacrificial material (e.g., polymer) on each side of the holes in the y-direction. A portion of the sacrificial material may be reformed adjacent to the first sacrificial material boundary 420-a and the second sacrificial material boundary 420-b, and then another sacrificial material boundary 420 may be formed on each side. These formation phases may be performed iteratively until the sacrificial material boundaries 420-c and 420-d are formed, and a remainder of the stack of materials 405 is re-filled with the sacrificial material.

Such techniques may result in multiple sacrificial material boundaries 420 being formed at each sidewall 425 of each memory slot 415. The memory slots 415 may then be recessed to expose the sacrificial material boundaries 420 (e.g., layers of the oxide material and sacrificial material may be recessed from sidewalls of the memory slots 415), which may form notches at the sidewall 425-a and the sidewall 425-b. For example, the sacrificial material boundaries 420 may protrude into the memory slots 415 a further distance than the sacrificial material and the oxide material layers within the stack, as described and illustrated with reference to FIG. 3F. Regions between two adjacent sacrificial material boundaries 420 may thereby be referred to as recesses.

The memory slots 415 may be filled with materials similar to those described with reference to FIG. 3G. For example, a separation material (e.g., blocking oxide) may be deposited to extend along the sidewall 425-a and the sidewall 425-b of each memory slot 415, a storage material may be deposited to extend along the sidewall 425-a and the sidewall 425-b of each memory slot 415 and line the separation material, and a second separation material may be deposited to extend along the sidewall 425-a and the sidewall 425-b of each memory slot 415 and line the storage material. The materials may be formed around the notches formed by the protruding sacrificial material boundaries 420.

A metal material forming memory cell channels may be deposited in a remaining space between each notch formed from the sacrificial material boundaries 420, such that each memory cell channel at a sidewall 425 of a memory slot 415 is separated from other memory cell channels by the second separation material (e.g., the memory cell channels are separated based on extending between at least two notches at a sidewall 425). In some cases, the sidewall 425-a may include a first set of notches and a first set of memory cell channels and the sidewall 425-b may include a second set of notches and a second set of memory cell channels, where each second notch at the sidewall 425-b may align with a first notch at the sidewall 425-a and each second memory cell channel at the sidewall 425-b may align with a first memory cell channel at the sidewall 425-a (e.g., in the x-direction).

The layers of sacrificial material of the stack of materials 405 may be removed and replaced with a metal material to form word lines at one or more layers of the metal material. The metal material may replace the sacrificial material boundaries 420 such that each notch protruding into the memory slots 415 is at least partially filled with the metal material. In some examples, the holes 410 may be filled with a structural material or other material. One or more bit lines may contact each memory slot 415 via a bit line contact on top of the memory slot 415. The memory cells within the stack of materials 405 may be accessed by activation of respective word lines and bit lines, as described herein. The memory architecture 400 thereby supports increased memory cell density while preventing interference between memory cell channels by separating memory cell channels, within a memory slot 415, with a separation material.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 1: An apparatus, including: a substrate; a stack including a plurality of layers of an oxide material and a plurality of layers of a metal material stacked above the substrate in a vertical direction; a first pillar extending through the stack in the vertical direction; and a plurality of second pillars extending through the stack in the vertical direction, the plurality of second pillars each at least partially surrounding the first pillar, where each second pillar of the plurality of second pillars includes a respective plurality of memory cell channels extending through the stack in the vertical direction and includes a separation material positioned between each memory cell channel of the respective plurality of memory cell channels.
Aspect 2: The apparatus of aspect 1, where each second pillar of the plurality of second pillars includes: an oxide liner that extends along at least a portion of a sidewall of each second pillar; a plurality of segments of the separation material in contact with the oxide liner, where each segment of the plurality of segments extends through the stack in the vertical direction and is separated from each other segment of the plurality of segments; and a storage material that extends along one or more sidewalls of each segment of the separation material and that extends along at least a portion of the oxide liner between each segment of the separation material.
Aspect 3: The apparatus of aspect 2, where each second pillar of the plurality of second pillars includes: a second separation material that lines the storage material and is positioned between the respective plurality of memory cell channels within each second pillar and the storage material.
Aspect 4: The apparatus of any of aspects 2 through 3, where each memory cell channel of the respective plurality of memory cell channels is coupled with a plurality of memory cells including the storage material within the plurality of layers of the metal material.
Aspect 5: The apparatus of any of aspects 2 through 4, where the first pillar includes the oxide liner, the separation material, and the storage material.
Aspect 6: The apparatus of any of aspects 1 through 5, where each memory cell channel of the respective plurality of memory cell channels is at least partially surrounded by a second separation material.
Aspect 7: The apparatus of any of aspects 1 through 6, where the plurality of second pillars includes six pillars positioned in a hexagonal shape around the first pillar.
Aspect 8: The apparatus of any of aspects 1 through 7, where the plurality of second pillars includes four pillars positioned in a square shape around the first pillar.
Aspect 9: The apparatus of any of aspects 1 through 8, further including: a plurality of contacts, each contact of the plurality of contacts coupled with a respective second pillar of the plurality of second pillars; and a plurality of bit lines, each bit line of the plurality of bit lines coupled with a respective contact of the plurality of contacts.
Aspect 10: The apparatus of any of aspects 1 through 9, where the separation material includes the oxide material.

An apparatus is described. The following provides an overview of aspects of the apparatus as described herein:
Aspect 11: An apparatus, including: a substrate; a stack including a plurality of layers of an oxide material and a plurality of layers of a metal material stacked above the substrate in a vertical direction; and a pillar extending through the stack in the vertical direction, the pillar including: a sidewall that forms a plurality of notches at each layer of the plurality of layers of the metal material, where each notch of the plurality of notches is at least partially filled with a portion of the metal material; and a plurality of memory cell channels extending through the stack in the vertical direction, where each memory cell channel of the plurality of memory cell channels is separate from each other memory cell channel of the plurality of memory cell channels based at least in part on the memory cell channel extending between at least two notches of the plurality of notches at each layer of the plurality of layers of the metal material.
Aspect 12: The apparatus of aspect 11, further including: a plurality of word lines at each layer of the plurality of layers of the metal material, where each word line of the plurality of word lines at least partially surrounds the pillar and includes the portion of the metal material within each notch of the plurality of notches.
Aspect 13: The apparatus of any of aspects 11 through 12, where the pillar further includes: a separation material that extends along the sidewall of the pillar, where the separation material forms each notch of the plurality of notches and extends, along each notch, between each pair of adjacent memory cell channels of the plurality of memory cell channels.
Aspect 14: The apparatus of aspect 13, where the pillar further includes: a storage material that extends between the separation material and the plurality of memory cell channels.
Aspect 15: The apparatus of aspect 14, where the pillar further includes: a second separation material that extends between the storage material and the plurality of memory cell channels, where the second separation material is in contact with at least a portion of each memory cell channel of the plurality of memory cell channels.
Aspect 16: The apparatus of any of aspects 14 through 15, where each memory cell channel of the plurality of memory cell channels is coupled with a plurality of memory cells including the storage material within the plurality of layers of the metal material.

An apparatus is described. The following provides an overview of aspects of the apparatus as described herein:
Aspect 17: An apparatus, including: a substrate; a stack including a plurality of layers of an oxide material and a plurality of layers of a metal material stacked above the substrate in a vertical direction; a pillar extending through the stack in the vertical direction; and a memory slot extending through the stack in the vertical direction, the memory slot including: a first sidewall that forms a plurality of notches at each layer of the plurality of layers of the metal material, where each notch of the plurality of notches is at least partially filled with a portion of the metal material; and a plurality of memory cell channels extending through the stack in the vertical direction, where each memory cell channel of the plurality of memory cell channels is separate from each other memory cell channel of the plurality of memory cell channels based at least in part on the memory cell channel extending between at least two notches of the plurality of notches.
Aspect 18: The apparatus of aspect 17, where the memory slot further includes: a second sidewall opposite to the first sidewall that forms a plurality of second notches at each layer of the plurality of layers of the metal material, where each second notch of the plurality of second notches is filled with a second portion of the metal material; and a plurality of second memory cell channels extending through the stack in the vertical direction, where each second memory cell channel of the plurality of second memory cell channels is separate from each other second memory cell channel of the plurality of second memory cell channels based at least in part on the second memory cell channel extending between at least two second notches of the plurality of second notches.
Aspect 19: The apparatus of aspect 18, where: each second notch of the plurality of second notches aligns, within the memory slot, with a corresponding notch of the plurality of notches; and each second memory cell channel of the plurality of second memory cell channels aligns, within the memory slot, with a corresponding memory cell channel of the plurality of memory cell channels.
Aspect 20: The apparatus of any of aspects 17 through 19, where the memory slot further includes: a separation material that extends along the first sidewall and a second sidewall of the memory slot and that forms each notch of the plurality of notches, where the separation material extends, along each notch, between each pair of adjacent memory cell channels of the plurality of memory cell channels.
Aspect 21: The apparatus of aspect 20, where the memory slot further includes: a storage material that extends between the separation material and the plurality of memory cell channels.
Aspect 22: The apparatus of aspect 21, where the memory slot further includes: a second separation material that extends between the storage material and the plurality of memory cell channels, where the second separation material is in contact with at least a portion of each memory cell channel of the plurality of memory cell channels.
Aspect 23: The apparatus of any of aspects 21 through 22, where each memory cell channel of the plurality of memory cell channels is coupled with a plurality of memory cells including the storage material within the plurality of layers of the metal material.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a substrate;
a stack comprising a plurality of layers of an oxide material and a plurality of layers of a metal material stacked above the substrate in a vertical direction;
a first pillar extending through the stack in the vertical direction; and
a plurality of second pillars extending through the stack in the vertical direction, the plurality of second pillars each at least partially surrounding the first pillar, wherein each second pillar of the plurality of second pillars comprises a respective plurality of memory cell channels extending through the stack in the vertical direction and comprises a separation material positioned between each memory cell channel of the respective plurality of memory cell channels.

2. The apparatus of claim 1, wherein each second pillar of the plurality of second pillars comprises:
an oxide liner that extends along at least a portion of a sidewall of each second pillar;
a plurality of segments of the separation material in contact with the oxide liner, wherein each segment of the plurality of segments extends through the stack in the vertical direction and is separated from each other segment of the plurality of segments; and
a storage material that extends along one or more sidewalls of each segment of the separation material and that extends along at least a portion of the oxide liner between each segment of the separation material.

3. The apparatus of claim 2, wherein each second pillar of the plurality of second pillars comprises:
a second separation material that lines the storage material and is positioned between the respective plurality of memory cell channels within each second pillar and the storage material.

4. The apparatus of claim 2, wherein each memory cell channel of the respective plurality of memory cell channels is coupled with a plurality of memory cells comprising the storage material within the plurality of layers of the metal material.

5. The apparatus of claim 2, wherein the first pillar comprises the oxide liner, the separation material, and the storage material.

6. The apparatus of claim 1, wherein each memory cell channel of the respective plurality of memory cell channels is at least partially surrounded by a second separation material.

7. The apparatus of claim 1, wherein the plurality of second pillars comprises six pillars positioned in a hexagonal shape around the first pillar.

8. The apparatus of claim 1, wherein the plurality of second pillars comprises four pillars positioned in a square shape around the first pillar.

9. The apparatus of claim 1, further comprising:
a plurality of contacts, each contact of the plurality of contacts coupled with a respective second pillar of the plurality of second pillars; and
a plurality of bit lines, each bit line of the plurality of bit lines coupled with a respective contact of the plurality of contacts.

10. The apparatus of claim 1, wherein the separation material comprises the oxide material.

11. An apparatus, comprising:
a substrate;
a stack comprising a plurality of layers of an oxide material and a plurality of layers of a metal material stacked above the substrate in a vertical direction; and
a pillar extending through the stack in the vertical direction, the pillar comprising:
a sidewall that forms a plurality of notches at each layer of the plurality of layers of the metal material, wherein each notch of the plurality of notches is at least partially filled with a portion of the metal material; and
a plurality of memory cell channels extending through the stack in the vertical direction, wherein each memory cell channel of the plurality of memory cell channels is separate from each other memory cell channel of the plurality of memory cell channels based at least in part on the memory cell channel extending between at least two notches of the plurality of notches at each layer of the plurality of layers of the metal material.

12. The apparatus of claim 11, further comprising:
a plurality of word lines at each layer of the plurality of layers of the metal material, wherein each word line of the plurality of word lines at least partially surrounds the pillar and comprises the portion of the metal material within each notch of the plurality of notches.

13. The apparatus of claim 11, wherein the pillar further comprises:
a separation material that extends along the sidewall of the pillar, wherein the separation material forms each notch of the plurality of notches and extends, along each notch, between each pair of adjacent memory cell channels of the plurality of memory cell channels.

14. The apparatus of claim 13, wherein the pillar further comprises:
a storage material that extends between the separation material and the plurality of memory cell channels.

15. The apparatus of claim 14, wherein the pillar further comprises:
a second separation material that extends between the storage material and the plurality of memory cell channels, wherein the second separation material is in contact with at least a portion of each memory cell channel of the plurality of memory cell channels.

16. The apparatus of claim 14, wherein each memory cell channel of the plurality of memory cell channels is coupled with a plurality of memory cells comprising the storage material within the plurality of layers of the metal material.

17. An apparatus, comprising:
a substrate;
a stack comprising a plurality of layers of an oxide material and a plurality of layers of a metal material stacked above the substrate in a vertical direction;
a pillar extending through the stack in the vertical direction; and
a memory slot extending through the stack in the vertical direction, the memory slot comprising:
a first sidewall that forms a plurality of notches at each layer of the plurality of layers of the metal material, wherein each notch of the plurality of notches is at least partially filled with a portion of the metal material; and
a plurality of memory cell channels extending through the stack in the vertical direction, wherein each memory cell channel of the plurality of memory cell channels is separate from each other memory cell channel of the plurality of memory cell channels based at least in part on the memory cell channel extending between at least two notches of the plurality of notches.

18. The apparatus of claim 17, wherein the memory slot further comprises:
a second sidewall opposite to the first sidewall that forms a plurality of second notches at each layer of the plurality of layers of the metal material, wherein each second notch of the plurality of second notches is filled with a second portion of the metal material; and
a plurality of second memory cell channels extending through the stack in the vertical direction, wherein each second memory cell channel of the plurality of second memory cell channels is separate from each other second memory cell channel of the plurality of second memory cell channels based at least in part on the second memory cell channel extending between at least two second notches of the plurality of second notches.

19. The apparatus of claim 18, wherein:
each second notch of the plurality of second notches aligns, within the memory slot, with a corresponding notch of the plurality of notches; and
each second memory cell channel of the plurality of second memory cell channels aligns, within the memory slot, with a corresponding memory cell channel of the plurality of memory cell channels.

20. The apparatus of claim 17, wherein the memory slot further comprises:
a separation material that extends along the first sidewall and a second sidewall of the memory slot and that forms each notch of the plurality of notches, wherein the separation material extends, along each notch, between each pair of adjacent memory cell channels of the plurality of memory cell channels.

21. The apparatus of claim 20, wherein the memory slot further comprises:
a storage material that extends between the separation material and the plurality of memory cell channels.

22. The apparatus of claim 21, wherein the memory slot further comprises:
a second separation material that extends between the storage material and the plurality of memory cell channels, wherein the second separation material is in contact with at least a portion of each memory cell channel of the plurality of memory cell channels.

23. The apparatus of claim 21, wherein each memory cell channel of the plurality of memory cell channels is coupled with a plurality of memory cells comprising the storage material within the plurality of layers of the metal material.
